(19) United States
(12) Patent Application Publication
(10) Pub. No.: US 2013/0140546 A1
(43) Pub. Date: Jun. 6, 2013

(54) HYGROSCOPIC FILLER FOR ORGANIC EL GETTER, METHOD FOR MANUFACTURING THE SAME, AND ORGANIC EL DEVICE INCLUDING THE SAME

(71) Applicants: Ji Yeon LEE, Uiwang-si (KR); Mi Sun KIM, Uiwang-si (KR); Kil Sung LEE, Uiwang-si (KR); Min Haeng CHO, Uiwang-si (KR); Kie Hyun NAM, Seongnam-si (KR); Jung Woo MOON, Suwon-si (KR); Ji Sil LEE, Uijeongbu-si (KR)

(72) Inventors: Ji Yeon LEE, Uiwang-si (KR); Mi Sun KIM, Uiwang-si (KR); Kil Sung LEE, Uiwang-si (KR); Min Haeng CHO, Uiwang-si (KR); Kie Hyun NAM, Seongnam-si (KR); Jung Woo MOON, Suwon-si (KR); Ji Sil LEE, Uijeongbu-si (KR)

(21) Appl. No.: 13/752,911

(22) Filed: Jan. 29, 2013

Related U.S. Application Data
(63) Continuation of application No. PCT/KR2010/009233, filed on Dec. 22, 2010.

(30) Foreign Application Priority Data
Jul. 30, 2010 (KR) 10-2010-0074223

(51) Int. Cl. H01L 51/52

(52) U.S. Cl. CPC H01L 51/5259
USPC 257/40; 428/304.4; 442/118; 428/319.9; 428/319.3; 428/315.5; 428/319.1; 428/319.7; 427/372.2; 524/503

(57) ABSTRACT

A hygroscopic filler for an organic EL getter, a method of manufacturing the same, and an organic EL device including the same, the hygroscopic filler including a sheet having pores; and a mixture of an organic binder and a hygroscopic material, the mixture being secured to the sheet.

### CROSS-REFERENCE TO RELATED APPLICATIONS

This application is a continuation of pending International Application No. PCT/KR2010/009233, entitled “HYGROSCOPIC FILLER FOR ORGANIC EL GETTER, METHOD FOR MANUFACTURING THE SAME, AND ORGANIC EL DEVICE INCLUDING THE SAME,” which was filed on Dec. 22, 2010, the entire contents of which are hereby incorporated by reference.

Korean Patent Application No. 10-2010-0074223 filed on Jul. 30, 2010, in the Korean Intellectual Property Office, and entitled: “HYGROSCOPIC FILLER FOR ORGANIC EL GETTER, METHOD FOR MANUFACTURING THE SAME, AND ORGANIC EL DEVICE INCLUDING THE SAME,” is incorporated by reference herein in its entirety.

### BACKGROUND

1. Field

Embodiments relate to a hygroscopic filler for organic EL getters, a method for manufacturing the same, and an organic EL device including the same.

2. Description of the Related Art

An organic electroluminescent device (organic EL device) is a self-light emitting device having a structure wherein a thin layer, e.g., an organic EL layer including a fluorescent or phosphorescent organic compound, is interposed between a pair of electrodes e.g., positive and negative electrodes, and emits light upon inactivation of an exciton generated in the thin layer through recombination of a hole and an electron injected into the thin layer.

### SUMMARY

Embodiments are directed to a hygroscopic filler for organic EL getters, a method for manufacturing the same, and an organic EL device including the same.

The embodiments may be realized by providing a hygroscopic filler for an organic electroluminescent (EL) getter, the hygroscopic filler including a sheet having pores; and a mixture of an organic binder and a hygroscopic material, the mixture being secured to the sheet.

The sheet may have a porosity of about 5% to about 95%.

The sheet may be a non-woven fabric, a woven fabric, or a latex sheet.

The non-woven fabric and the woven fabric may include one or more of a polyvinyl acetate resin, a polyvinyl pyrrolidone resin, a polyester resin, a polyolefin resin, a (meth)acrylate resin, a polycarbonate resin, an acrylonitrile resin, a cellulose acetate, an epoxy resin, a phenoxy resin, a siloxane resin, a sulfone resin, a polyamide resin, a polyurethane resin, a polyvinyl resin, a urethane acrylate resin, or a fluorine resin; and the latex sheet may include one or more of a polyurethane, a polybutadiene, a nitrile rubber, an acryl rubber, or a polysiloxane.

The pores may have an average diameter of about 0.1 μm to about 200 μm.

The mixture of the organic binder and the hygroscopic material may be physically or chemically secured to the sheet.

The mixture of the organic binder and the hygroscopic material may be secured to the sheet via impregnation.

The mixture of the organic binder and the hygroscopic material may be secured to one surface of the sheet by forming a separate cover layer or coating layer.

The organic binder may have a glass transition temperature of about −60° C. to about 170° C.

The organic binder may have a glass transition temperature of about −60° C. to about 80° C.

The organic binder may include one or more of a polyvinyl acetate resin, a polyvinyl pyrrolidone resin, a polyester resin, a polyolefin resin, a (meth)acrylate resin, a polycarbonate resin, an acrylonitrile resin, a cellulose acetate, an epoxy resin, a phenoxy resin, a siloxane resin, a sulfone resin, a polyamide resin, a polyurethane resin, a polyvinyl resin, a urethane acrylate resin, or a fluorine resin.

The hygroscopic material may have an average particle diameter of about 0.01 μm to about 200 μm.

The hygroscopic material may include one or more of a molecular sieve zeolite, a silica gel, a carbonate, a clay, a metal oxide, a metal hydroxide, an alkali earth metal oxide, a sulfate, a metal halide, a perchlorate, an organic metal compound, an organic/inorganic hybrid material particle enabling physical or chemical absorption, a modified particle having a polymer resin continuously or discontinuously secured to a surface thereof, or mixtures thereof.

The hygroscopic material may include the modified particle, the modified particle including a polymer resin secured to a surface of the hygroscopic material in the form of a coating layer or in the form of projections on the surface of the hygroscopic material.

The sheet may include a non-woven fabric, and the hygroscopic material may be secured in an amount of about 0.1 wt % to about 99 wt % to the sheet.

The hygroscopic filler may have an adhesive strength of about 1 gf/cm² to about 100,000 gf/cm², as measured according to a peeling test at a test speed of 50 mm/min.

The hygroscopic filler may further include a coating layer.

The coating layer may be on a surface of the sheet opposite to a surface of the sheet to which the mixture of the organic binder and the hygroscopic material is secured.

The coating layer may include one or more of a polyvinyl acetate resin, a polyvinyl pyrrolidone resin, a polyester resin, a polyolefin resin, a (meth)acrylate resin, a polycarbonate resin, an acrylonitrile resin, a cellulose acetate, an epoxy resin, a phenoxy resin, a siloxane resin, a sulfone resin, a polyamide resin, a polyurethane resin, a polyvinyl resin, a urethane acrylate resin, or a fluorine resin.

The hygroscopic filler may have a thickness of about 5 μm to about 500 μm.

The embodiments may also be realized by providing a method of manufacturing a hygroscopic filler for an organic electroluminescent (EL) getter, the method including preparing a sheet having pores; impregnating a mixture of a hygroscopic material and a binder into the sheet; and drying or curing the sheet having the mixture impregnated therein to secure the binder and the hygroscopic material to the sheet.

The mixture of the hygroscopic material and the binder may be present in an amount of about 10 parts by weight to about 2,000 parts by weight, based on 100 parts by weight of the sheet, and a weight ratio of the hygroscopic material to the binder may be about 1:9 to about 9:1 in terms of parts by weight.

The mixture may further include a solvent.

The method may include the curing, the curing including UV curing or heat curing.

The embodiments may also be realized by providing a method of manufacturing a hygroscopic filler for an organic electroluminescent (EL) getter, the method including preparing a sheet having pores; coating a mixture of a hygroscopic material and a binder on the sheet; and drying or curing the sheet having the mixture coated thereon to secure the binder and the hygroscopic material to the sheet.

The embodiments may also be realized by providing an organic electroluminescent device including a getter including the hygroscopic filler for an organic EL getter according to an embodiment.

The embodiments may also be realized by providing an organic electroluminescent (EL) device, including a substrate; an organic electroluminescent unit on one surface of the substrate, the organic electroluminescent unit including a first electrode, an organic light emitting layer, and a second electrode; a sealing cap coupled with the substrate to accommodate the organic electroluminescent unit therein; and a getter within the sealing cap, the getter including the hygroscopic filler for an organic EL getter according to an embodiment.

### BRIEF DESCRIPTION OF THE DRAWINGS

Features will become apparent to those of skill in the art by describing in detail exemplary embodiments with reference to the attached drawings in which:

FIG. 1 illustrates a schematic sectional view of a sealing structure of an organic EL device on which a getter is mounted.

FIGS. 2(a) and 2(b) illustrate schematic sectional views of a sheet having pores according to an embodiment.

FIG. 3 illustrates a schematic sectional view of a hygroscopic filler for an organic EL getter according to an embodiment.

FIG. 4 illustrates a schematic sectional view of a hygroscopic filler for an organic EL getter according to an embodiment.

FIGS. 5(a) and 5(b) illustrate schematic sectional views of a hygroscopic filler for an organic EL getter, which has a coating layer, according to an embodiment.

FIG. 6 illustrates a sectional view of an organic EL device according to an embodiment.

### DESCRIPTION OF REFERENCE NUMERALS

| | |
|---|---|
| 10: sheet having pores | 10a: fiber |
| 10b: pore | 20: hygroscopic material |
| 30: binder | 40: cover layer |
| 50: coating layer | 100: hygroscopic filler |
| 110: substrate | 120: sealing cap |
| 130: organic electroluminescent unit | 140: drying means |

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

FIG. 1 illustrates a schematic sectional view of a sealing structure of an organic EL device on which a getter is mounted. As shown in FIG. 1, an organic EL device may include a substrate 110, an organic electroluminescent unit 130 on one surface of the substrate 110, and a sealing cap 120 coupled with the substrate 110 and accommodating the organic electroluminescent unit 130 therein. A drying means or getter 140 for absorbing moisture may be on at least part of the sealing cap 120.

The drying means may be realized in the form of a sealed moisture permeable pocket receiving therein hygroscopic powders, pellets formed by compressing the hygroscopic powders, and/or a film formed by mixing the hygroscopic powders with a polymer binder.

The pocket type drying means may be thicker than the film type drying means and may cause pocket swelling and/or powder falling on a device at high temperature. In addition, the pellet type drying means may have difficulty producing a thin layer and low durability.

A film type additive produced by mixing an inorganic filler and a polymer binder may have a simple configuration and may be manufactured into a thin layer having a thickness of several micrometers or less. However, this type of additive may exhibit a significant separation of powders from the getter and significantly low moisture absorption rate due to the polymer binder film.

In addition, silicone oil may be used, but it may be difficult to reach a practical level applicable to an OLED even after dehydration of the silicone oil for a long period of time. Moreover, addition of the silicone oil may require a structure for injecting the liquid oil into the display device and may complicate the process.

Hygroscopic materials may include, e.g., calcium oxide (CaO), which may not generate outgassing during moisture absorption and may help prevent the absorbed moisture from escaping therefrom. However, when a loading quantity of CaO particles is increased in order to help improve the moisture absorption rate per unit area, a resin for supporting the CaO particles, e.g., a monomer or a polymer, may become a cake, thereby providing weak support and low impact resistance. Further, as the thickness of the filling film decreases corresponding to decrease in thickness of an OLED display, there is an increasing possibility of the CaO particles directly contacting the device, causing an undesirable decrease in lifespan of the device.

A hygroscopic filler for an organic EL getter according to an embodiment may include a sheet having pores and a mixture of an organic binder and a hygroscopic material secured to or coupled with the sheet.

The sheet may be formed with pores, which may have an average diameter of about 0.1 μm to about 200 μm, e.g., about 0.5 μm to about 100 μm or about 1 μm to about 50 μm. The sheet may have a porosity of about 5% to about 95%, e.g., about 10% to about 80% or about 20% to about 70%. As such, the sheet has the pores, so that moisture and gas (e.g., oxygen) may smoothly pass through the sheet to react with the hygroscopic material. In addition, when the sheet has a porosity within the above-described range, the hygroscopic filler may have a good moisture absorption rate and may advantageously serve to buffer between a moisture absorption layer and a device.

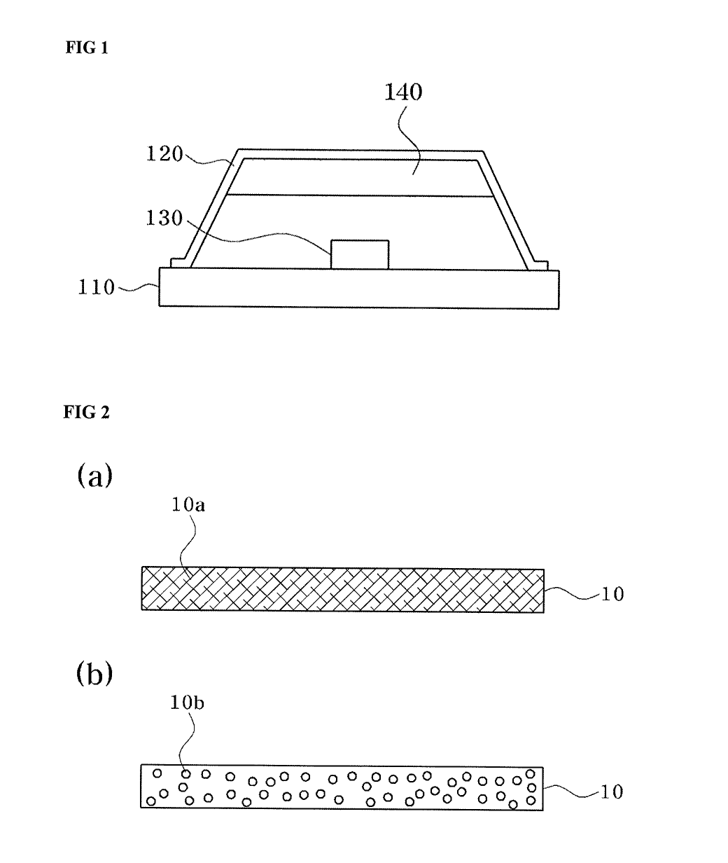

FIG. 2 schematically illustrates a structure of the sheet 10 according to an embodiment. In an implementation, the sheet 10 may be comprised of a non-woven fabric or a woven fabric, as shown in FIG. 2(a), or may be a porous latex sheet 10b, as shown in FIG. 2(b).

When the sheet 10 is formed of the non-woven fabric or the woven fabric (as shown in FIG. 2(a)), fibers 10a (having an average diameter of about 0.1 μm to about 200 μm) may be regularly or irregularly entangled to provide a web structure, and pores may be formed between the fibers to provide porosity. In an implementation, the fibers 10a may have an average diameter of about 0.1 μm to about 200 μm, e.g., about 0.5 μm to about 100 μm or about 0.5 μm to about 50 μm. Within this range of the average diameter of the fibers, the sheet may secure the hygroscopic material, may impart high mechanical strength of a fibrous structure in a diameter region of several micrometers (instead of a nano-web structure), and may form uniform pores to thereby help prevent deterioration in hygroscopic efficiency caused by the binder. The fibers may have a length of about 0.1 mm to about 100 mm, e.g., about 0.5 mm to about 50 mm or about 1 mm to about 30 mm.

The fibers forming the non-woven fabric or the woven fabric may include, e.g., a polyvinyl acetate (PVAc) resin, a polyvinyl pyrrolidone (PVP) resin, a polyester resin, a polyolefin resin, a (meth)acrylate resin, a polycarbonate resin, an acrylonitrile resin, a cellulose acetate, an epoxy resin, a phenoxy resin, a siloxane resin, a sulfone resin, a polyamide resin, a polyurethane resin, a polyvinyl resin, a urethane acrylate resin, and a fluorine resin, or the like. These components may be used alone or in combination thereof.

The latex sheet may include, e.g., polyurethane, polybutadiene, nitrile rubber, acryl rubber, polysiloxane, or the like. These components may be used alone or in combination thereof. The latex sheet may be formed from natural or synthetic polymers

In an implementation, the mixture of the organic binder and the hygroscopic material may be physically or chemically secured to the sheet. In an implementation, the mixture of the organic binder and the hygroscopic material may be secured to the sheet via impregnation.

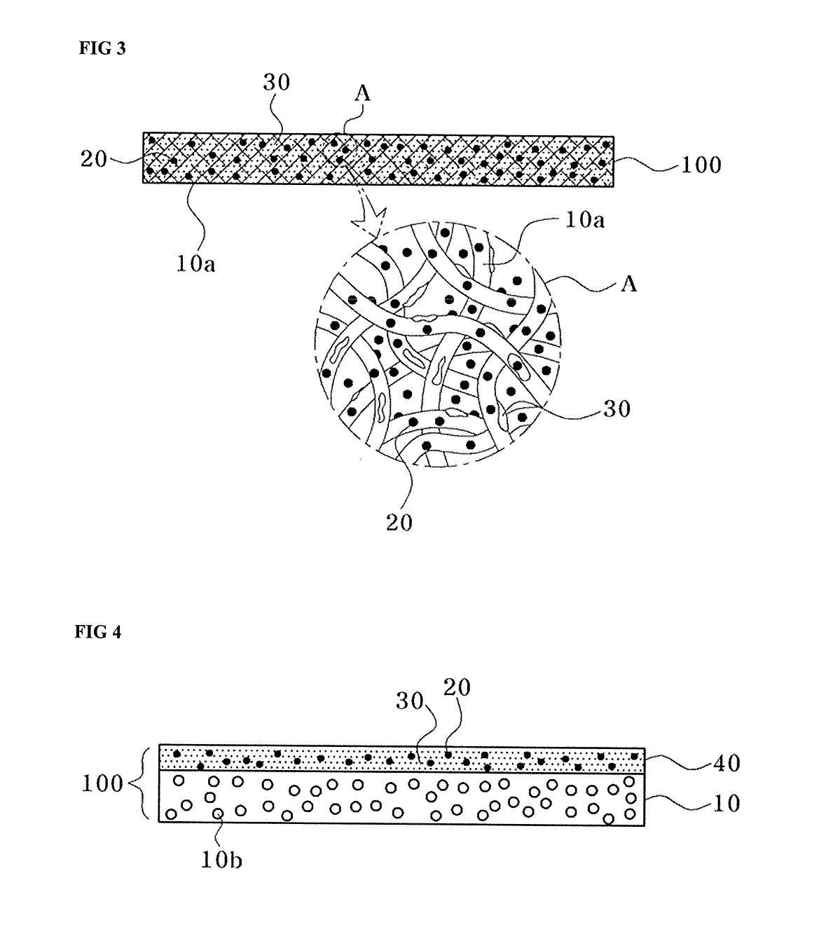

FIG. 3 schematically illustrates a structure of a hygroscopic filler 100, which may include the hygroscopic material 20 and the organic binder 30 impregnated into the non-woven fabric, according to an embodiment. For example, the organic binder 30 may form a coating layer on the fibers 10a constituting the non-woven fabric or may be present in pores of the non-woven fabric. The organic binder 30 may bind the fibers 10a to each other or may be present between the fibers 10a and the pores. Further, the organic binder 30 may be interposed between the fibers 10a and the hygroscopic material 20 to secure the hygroscopic material 20 to the fibers 10a, or may cover the hygroscopic material 20 adjoining the fibers 10a to secure the hygroscopic material 20 thereto.

The hygroscopic filler (into which the mixture of the organic binder and the hygroscopic material is impregnated) may be produced by the following method. The method may include preparing a sheet having pores; impregnating a mixture of a hygroscopic material and a binder into the sheet; and drying or curing the sheet to secure the binder and the hygroscopic material, e.g., to the sheet. A suitable sheet comprised of a non-woven fabric, a woven fabric, or latex that has pores therein may be used. In an implementation, a non-woven fabric sheet may be used.

In an implementation, the mixture of the organic binder and the hygroscopic material may be secured to the sheet by forming a separate cover layer on one surface of the sheet.

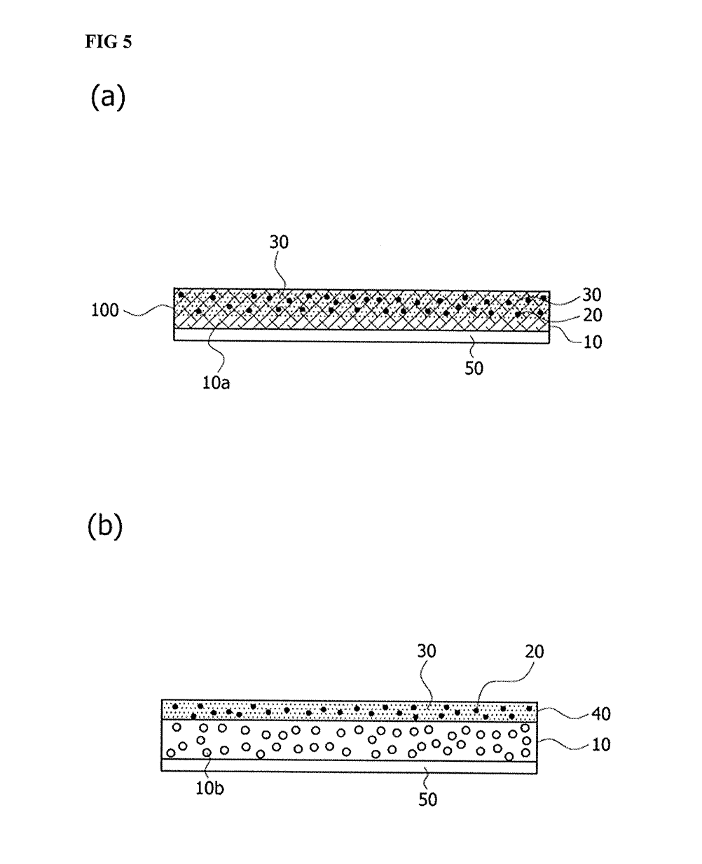

FIG. 4 schematically illustrates the structure of the hygroscopic filler 100, which may include a separate cover layer 40 formed of the mixture of the hygroscopic material 20 and the organic binder 30 on the sheet 10 including the pores 10b, according to an embodiment.

The mixture of the organic binder and the hygroscopic material may include about 10 wt % to about 90 wt % of the hygroscopic material and about 10 wt % to about 90 wt % of the organic binder. Within this range, the organic binder may easily secure the hygroscopic material, e.g., to the sheet. In an implementation, the mixture may include about 10 wt % to about 70 wt % of the hygroscopic material and about 30 wt % to about 90 wt % of the organic binder, e.g., about 10 wt % to about 60 wt % of the hygroscopic material and about 40 wt % to about 90 wt % of the organic binder.

The binder may be formed of the same or different components from those of the non-woven fabric. The binder may have a glass transition temperature of about −60° C. to about 170° C., e.g., −60° C. to about 80° C. or about −60° C. to about 50° C. Within this range of glass transition temperature, the filler may be advantageously adhered to the sealing cap without using adhesives. In an implementation, the binder may include, e.g., a polyvinyl acetate (PVAc) resin, a polyvinyl pyrrolidone (PVP) resin, a polyester resin, a polyolefin resin, a (meth)acrylate resin, a polycarbonate resin, an acrylonitrile resin, a cellulose acetate, an epoxy resin, a phenoxy resin, a siloxane resin, a sulfone resin, a polyamide resin, a polyurethane resin, a polyvinyl resin, a urethane acrylate resin, and a fluorine resin, or the like. These components may be used alone or in combination thereof.

As shown in FIG. 3, the hygroscopic material 20 may be distributed on the fibers 10a or between the fibers 10a, and may be physically or chemically secured to the non-woven fabric or the woven fabric. In an implementation, the hygroscopic material may be coupled with the fibers via the binder, or may be secured to the fibers in such a way that the binder covers a bonded portion between the fibers and the hygroscopic material. Further, the fibers may be entangled with each other, whereby the hygroscopic material may be secured between the fibers.

The hygroscopic material may be evenly dispersed throughout the sheet, e.g., the non-woven fabric or the woven fabric. Alternatively, the hygroscopic material may be secured to one side of the sheet, e.g., the non-woven fabric.

In an implementation, as shown in FIG. 4, the hygroscopic material 20 may be secured to one side of the sheet 10 by forming a separate layer together with the organic binder 30, e.g., a cover layer 40. The cover layer 40 may be formed on one or both sides of the sheet 10.

The hygroscopic material may include, e.g., a molecular sieve zeolite, a silica gel, a carbonate, a clay, a metal oxide, a metal hydroxide, an alkali earth metal oxide, a sulfate, a metal halide, a perchlorate, an organic metal compound, an organic/inorganic hybrid material particle enabling physical or chemical absorption; or a modified particle having a polymer resin continuously or discontinuously secured to a surface thereof. These materials may be used alone or in combination thereof.

Examples of the carbonate may include sodium carbonate, sodium bicarbonate, and the like.

Examples of the metal oxide may include lithium oxide (Li₂O), sodium oxide (Na₂O), potassium oxide (K₂O), and the like. Examples of the alkali earth metal oxide may include barium oxide (BaO), calcium oxide (CaO), magnesium oxide (MgO), and the like. Examples of the metal hydroxide may include calcium hydroxide, potassium hydroxide, and the like. Examples of the sulfate may include lithium sulfate (Li₂SO₄), sodium sulfate (Na₂SO₄), calcium sulfate (CaSO₄), magnesium sulfate (MgSO₄), cobalt sulfate (CoSO₄), gallium sulfate (Ga₂(SO₄)₃), titanium sulfate (Ti(SO₄)₂), nickel sulfate (NiSO₄), and the like. Examples of the metal halide may include calcium chloride (CaCl₂), magnesium chloride (MgCl₂), strontium chloride (SrCl₂), yttrium chloride (YCl₂), copper chloride (CuCl₂), cesium fluoride (CsF), tantalum fluoride (TaF₅), niobium fluoride (NbF₅), lithium bromide (LiBr), calcium bromide (CaBr₃), cerium bromide (CeBr₄), selenium bromide (SeBr₂), vanadium bromide (VBr₂), magnesium bromide (MgBr₂), barium iodide (BaI₂), magnesium iodide (MgI₂), and the like. Examples of the perchlorate may include barium perchlorate (Ba(ClO₄)₂), magnesium perchlorate (Mg(ClO₄)₂), and the like.

In an implementation, the hygroscopic material may include, e.g., metal oxides, metal hydroxides, alkali earth metal oxides, sulfates, or combination thereof.

The hygroscopic material may have an average particle size of about 0.1 μm to about 200 μm. In an implementation, the hygroscopic material may have an average particle size of about 0.5 μm to about 100 μm, e.g., about 1 μm to about 50 μm or about 3 μm to about 25 μm. Within this range, the hygroscopic material may advantageously provide high hygroscopic efficiency due to the high surface area thereof.

In an implementation, the mixture of the hygroscopic material and the binder may be present in the filler in an amount of about 10 parts by weight to about 2,000 parts by weight, based on 100 parts by weight of the sheet, e.g., about 100 parts by weight to about 1,000 parts by weight. Within this range, the sheet may provide high hygroscopic efficiency per unit area, film coating characteristics, and properties capable of forming non-woven fabrics. In an implementation, when the sheet having the pores is formed of the non-woven fabric, the hygroscopic material may be secured in an amount of about 0.1 wt % to about 99 wt % thereto, e.g., about 1 wt % to about 90 wt %.

In an implementation, the mixture may further include a solvent which may be volatilized during the manufacturing process. Examples of the solvent may include ethanol, methanol, propanol, butanol, isopropanol, methylethylketone, propylene glycol, 1-methoxy 2-propanol (PGM), isopropylcellulose (IPC), methyl cellosolve (MC), ethyl cellosolve (EC), acetone, methylethylketone, and the like. These solvents may be used alone or in combination thereof. The solvent may be present in an amount of about 100 parts by weight to about 2,000 parts by weight, based on 100 parts by weight of the mixture of the binder and the hygroscopic material, e.g., about 100 parts by weight to about 1,000 parts by weight.

Thus, the binder and the hygroscopic material may be secured by, e.g., impregnating the mixture containing the hygroscopic material into the sheet or by applying or coating the mixture to the sheet, followed by curing or drying the mixture. In an implementation, curing may be carried out by or may include UV curing or heat curing.

In an implementation, the hygroscopic filler may further include a coating layer formed on one surface of the sheet opposite the surface of the sheet into which the mixture of the organic binder and the hygroscopic material is impregnated, or on which the mixture is coated. For example, the mixture of the organic binder and the hygroscopic material may be impregnated into or coated on a first surface of the sheet, and the coating layer may be formed on a second surface of the sheet opposite the first surface of the sheet. The first surface may be an upper surface and the second surface may be a lower surface. Alternatively, the first surface may be a lower surface and the second surface may be an upper surface. FIGS. 5(a) and 5(b) illustrate one example of the hygroscopic filler including a coating layer 50 on one surface of the sheet 10 opposite the surface of the sheet 10 into which the mixture of the organic binder 30 and the hygroscopic material 20 is impregnated, or on which the mixture is coated. In an implementation, the coating layer 50 may be formed on the surface of the sheet 10 into which the mixture of the organic binder 30 and the hygroscopic material 20 is impregnated, or on which the mixture is coated (not illustrated).

As described above, the hygroscopic filler may further include the coating layer on the impregnated sheet, e.g., the impregnated non-woven fabric. Thus, the hygroscopic filler may maintain surface roughness even after the hygroscopic material absorbs moisture, may help improve film formability, and may help reduce and/or prevent the hygroscopic material, e.g., CaO particles, from directly touching the device.

In an implementation, the coating layer may include, e.g., a polyvinyl acetate (PVAc) resin, a polyvinyl pyrrolidone (PVP) resin, a polyester resin, a polyolefin resin, a (meth)acrylate resin, a polycarbonate resin, an acrylonitrile resin, a cellulose acetate, an epoxy resin, a phenoxy resin, a siloxane resin, a sulfone resin, a polyamide resin, a polyurethane resin, a polyvinyl resin, a urethane acrylate resin, a fluorine resin, or the like. In an implementation, the resin may contain no residual total volatile matter (RTVM) upon gas chromatography, particularly, in terms of device protection.

The coating layer may be comprised of a single layer or multiple layers. In an implementation, the coating layer may be a single layer. Further, the coating layer may be a porous or non-porous layer. The coating layer may have a thickness of about 0.1 μm to about 100 μm, e.g., about 1 μm to about 50 μm. Within this range, the coating layer may help protect the device from the hygroscopic material without deteriorating hygroscopic efficiency.

In an implementation, the hygroscopic filler may have a thickness of about 5 μm to about 500 μm, e.g., about 10 μm to about 200 μm. The hygroscopic filler may have an adhesive strength of about 1 gf/cm² to about 100,000 gf/cm², e.g., about 100 gf/cm² to about 10,000 gf/cm², as measured according to a peeling test at a test speed of 50 mm/min.

Organic EL Device

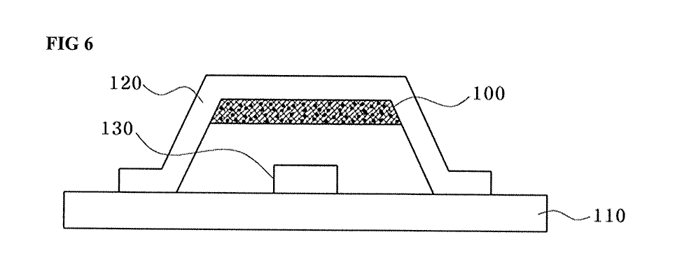

Another embodiment provides an organic EL device including the hygroscopic filler for an organic EL getter. FIG. 6 illustrates a sectional view of an organic EL device according to an embodiment. The organic EL device may include a substrate 110; an organic electroluminescent unit 130 formed on one surface of the substrate 110 (and including a first electrode, an organic light emitting layer, and a second electrode); a sealing cap 120 coupled with the substrate 110 to accommodate the organic electroluminescent unit 130 therein; and a drying means or dryer disposed inside the sealing cap 120. The drying means may include the hygroscopic filler 100 for an organic EL getter according to an embodiment.

The hygroscopic filler 100 may be secured to the sealing cap 120 by bonding or the like. In an implementation, the hygroscopic filler 100 may be secured to the sealing cap 120 by a binder having a glass transition temperature of about −60° C. to about 170° C. without using media such as adhesives.

Further, the location of the hygroscopic filler 100 on the sealing cap 120 is not limited to that shown in the figure, and the hygroscopic filler 100 may be secured to at least part of the sealing cap 120. In an implementation, the hygroscopic filler 100 may be interposed between the organic electroluminescent unit 130 and the sealing cap 120.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

A mixture was prepared by mixing 90 parts by weight of PVA (LM-10HD, KURARAY Co., Ltd.) as a binder, 10 parts by weight of metal oxide (CaO) as a hygroscopic material, and 1,900 parts by weight of methanol as a solvent, and then impregnated into a PP non-woven fabric (Core Wrap10, Toray Co., Ltd.) having an average thickness of 100 μm. The impregnated non-woven fabric was dried in a dryer (LI-DO02, LK Lab. Co., Ltd.) at 90° C. for 30 minutes to volatilize the solvent while securing the binder and the hygroscopic material thereto, thereby providing a hygroscopic filler.

### Examples 2-5

The hygroscopic filler was prepared by the same method as in Example 1 except that the amounts of the binder and the hygroscopic material were changed as listed in Table 1, below.

### Example 6

The hygroscopic filler was prepared by the same method as in Example 1 except that a separate cover layer was formed by depositing (coating) and drying the mixture on a latex sheet (Cheil Industries Inc.) having an average thickness of 100 μm instead of the PP non-woven fabric.

TABLE 1

| | | Hygroscopic | Film formability after | |
|---|---|---|---|---|
| | Binder | material | impregnation of PP | Hygroscopic |
| Example | (wt %) | (wt %) | non-woven fabrics | efficiency |
| 1 | 90 | 10 | OK | 3% |
| 2 | 70 | 30 | OK | 8% |
| 3 | 50 | 50 | OK | 13% |
| 4 | 30 | 70 | OK | 15% |
| 5 | 10 | 90 | NG | — |
| 6 | 90 | 10 | OK | 2% |

(1) Film formability: Film formability was evaluated by confirming whether the hygroscopic filler obtained by impregnating the mixture of the binder and the hygroscopic material into the non-woven fabric and drying the same was separated from a substrate in tack testing.

(2) Hygroscopic efficiency: Maximum hygroscopic efficiency was evaluated according to weight increase after 200 hours under moisture absorption conditions of 85° C. and 85%.

Evaluation after PVA Coating

PVA (LM-10HD, KURARAY Co., Ltd.) was coated to a thickness of 10 μm to each of the hygroscopic fillers prepared in Examples 1 to 6. Then, film formability after coating and hygroscopic efficiency were evaluated, and the results are shown in Table 2, below.

TABLE 2

| | | | Film formability after | |
|---|---|---|---|---|
| | | Hygroscopic | impregnation into PP | |
| | Binder | material | non-woven fabric | Hygroscopic |
| Example | (wt %) | (wt %) | and PVA coating | efficiency |
| 1 | 90 | 10 | OK | 2% |
| 2 | 70 | 30 | OK | 6% |
| 3 | 50 | 50 | OK | 12% |
| 4 | 30 | 70 | OK | 13% |
| 5 | 10 | 90 | OK | 17% |
| 6 | 90 | 10 | OK | 2% |

### Comparative Example 1

The hygroscopic filler was prepared by the same method as in Example 1 except that a mixture was prepared by mixing 90 parts by weight of PVA (LM-10HD, KURARAY Co., Ltd.), 10 parts by weight of metal oxide (CaO), and 1,900 parts by weight of methanol, and then cast under drying conditions at 80° C. to produce a 100 μm thick hygroscopic filler.

### Comparative Examples 2-5

The hygroscopic filler was prepared by the same method as in Comparative Example 1 except that the amounts of the binder and the hygroscopic material were changed as listed in Table 3, below.

TABLE 3

| Comparative | Binder | Hygroscopic | | Hygroscopic |
|---|---|---|---|---|
| Example | (wt %) | material (wt %) | Film formability | efficiency |
| 1 | 90 | 10 | OK | 4% |
| 2 | 70 | 30 | OK | 8% |
| 3 | 50 | 50 | OK | 13% |
| 4 | 30 | 70 | NG | — |
| 5 | 10 | 90 | NG | — |

As may be seen from Tables 1 to 3, the hygroscopic filler according to Examples 1-6 exhibited excellent hygroscopic efficiency, a high moisture absorption rate, and good film formability. For example, the coating layer formed on the hygroscopic filler further improved film formability by improving the bonding effect, thereby increasing the amount of the hygroscopic material therein. Further, the coating layer also exhibited hydrophilic properties and did not obstruct moisture absorption of the filler.

By way of summation and review, an organic layer and a metal layer of the organic EL device may be gradually oxidized due to, e.g., moisture infiltration or generation of oxygen, carbon monoxide, moisture, or the like, in the course of operation for a certain period of time. Accordingly, luminescent characteristics, e.g., brightness, luminescence uniformity, or the like, may be deteriorated. For example, a luminescent substance may be converted into a non-luminescent polymer through reaction with moisture to form dark spots, thereby causing deterioration in luminous efficacy while increasing device impedance due to low charge transport capability. Further, oxidation of the metal layer (used for a cathode) may result in flaking of the metal layer from or near the organic layer, thereby causing rapid deterioration in electron injection efficiency and a gradual reduction in the lifespan of the device.

The organic EL device may be vulnerable to moisture and oxygen. Thus, the organic EL device may be provided with a getter including a drying means or dryer capable of absorbing moisture in an encapsulation process for blocking moisture and oxygen.

A sticker type getter may be attached to opposite sides of a device. However, with the recent trend of increasing a size of an organic light emitting device (OLED), a significant increase in moisture absorption rate per unit area in order to protect the device from moisture may be desirable. In addition, a protective layer for protecting the device from impact should be formed.

The embodiments provide a hygroscopic filler for an organic EL getter, which does not generate undesirable dark spots and exhibits excellent hygroscopic efficiency. The embodiments also provide a hygroscopic filler for an organic EL getter, which exhibits a good moisture absorption rate. The embodiments also provide a hygroscopic filler for an organic EL getter, which has a high holding force to help prevent a hygroscopic material from being separated therefrom. The embodiments also provide a hygroscopic filler for an organic EL getter, which has high filling capability. The embodiments also provide a hygroscopic filler for an organic EL getter, which facilitates maximized loading quantity of a hygroscopic material. The embodiments also provide a hygroscopic filler for an organic EL getter, which may minimize device damage. The embodiments also provide a hygroscopic filler for an organic EL getter, which provides excellent workability and is easily fabricated. The embodiments also provide an organic EL device that includes the hygroscopic filler for an organic EL getter to improve light emitting characteristics and device lifespan by preventing deterioration of component films of the device.

Thus, the embodiments provide a hygroscopic filler for an organic EL getter, which does not generate dark spots, exhibits excellent properties in terms of hygroscopic efficiency, moisture absorption rate, holding force with respect to a hygroscopic material, filling capability and workability, maximizes the loading quantity of a hygroscopic material, can prevent device damage when distributed near the device, and permits easy fabrication thereof. In addition, the embodiments provide an organic EL getter composition including the hygroscopic filler for an organic EL getter to improve light emitting characteristics and lifespan by reducing and/or preventing deterioration of component films of the device.

The hygroscopic filler for an organic EL getter according to an embodiment may not generate dark spots, may exhibit excellent properties in terms of hygroscopic efficiency, moisture absorption rate, holding force with respect to a hygroscopic material, filling capability, and workability, and may help reduce and/or prevent damage of component films in a device. Therefore, the hygroscopic filler may be advantageously used for manufacturing an organic EL device having improved luminescent characteristics and lifespan.

The embodiments provide a hygroscopic filler for an organic EL getter that provides good hygroscopic and filling capabilities while facilitating an increase in loading quantity of the hygroscopic material and improving durability of an organic EL device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hygroscopic filler for an organic electroluminescent (EL) getter, the hygroscopic filler comprising:
a sheet having pores; and
a mixture of an organic binder and a hygroscopic material, the mixture being secured to the sheet.

2. The hygroscopic filler for an organic EL getter as claimed in claim 1, wherein the sheet has a porosity of about 5% to about 95%.

3. The hygroscopic filler for an organic EL getter as claimed in claim 1, wherein the sheet is a non-woven fabric, a woven fabric, or a latex sheet.

4. The hygroscopic filler for an organic EL getter as claimed in claim 3, wherein:
the non-woven fabric and the woven fabric includes one or more of a polyvinyl acetate resin, a polyvinyl pyrrolidone resin, a polyester resin, a polyolefin resin, a (meth)acrylate resin, a polycarbonate resin, an acrylonitrile resin, a cellulose acetate, an epoxy resin, a phenoxy resin, a siloxane resin, a sulfone resin, a polyamide resin, a polyurethane resin, a polyvinyl resin, a urethane acrylate resin, or a fluorine resin; and
the latex sheet includes one or more of a polyurethane, a polybutadiene, a nitrile rubber, an acryl rubber, or a polysiloxane.

5. The hygroscopic filler for an organic EL getter as claimed in claim 1, wherein the pores have an average diameter of about 0.1 μm to about 200 μm.

6. The hygroscopic filler for an organic EL getter as claimed in claim 1, wherein the mixture of the organic binder and the hygroscopic material is physically or chemically secured to the sheet.

7. The hygroscopic filler for an organic EL getter as claimed in claim 1, wherein the mixture of the organic binder and the hygroscopic material is secured to the sheet via impregnation.

8. The hygroscopic filler for an organic EL getter as claimed in claim 1, wherein the mixture of the organic binder and the hygroscopic material is secured to one surface of the sheet by forming a separate cover layer or coating layer.

9. The hygroscopic filler for an organic EL getter as claimed in claim 1, wherein the organic binder has a glass transition temperature of about −60° C. to about 170° C.

10. The hygroscopic filler according for an organic EL getter as claimed in claim 1, wherein the organic binder has a glass transition temperature of about −60° C. to about 80° C.

11. The hygroscopic filler for an organic EL getter as claimed in claim 1, wherein the organic binder includes one or more of a polyvinyl acetate resin, a polyvinyl pyrrolidone resin, a polyester resin, a polyolefin resin, a (meth)acrylate resin, a polycarbonate resin, an acrylonitrile resin, a cellulose acetate, an epoxy resin, a phenoxy resin, a siloxane resin, a sulfone resin, a polyamide resin, a polyurethane resin, a polyvinyl resin, a urethane acrylate resin, or a fluorine resin.

12. The hygroscopic filler for an organic EL getter as claimed in claim 1, wherein the hygroscopic material has an average particle diameter of about 0.01 μm to about 200 μm.

13. The hygroscopic filler for an organic EL getter as claimed in claim 1, wherein the hygroscopic material includes one or more of a molecular sieve zeolite, a silica gel, a carbonate, a clay, a metal oxide, a metal hydroxide, an alkali earth metal oxide, a sulfate, a metal halide, a perchlorate, an organic metal compound, an organic/inorganic hybrid material particle enabling physical or chemical absorption, a modified particle having a polymer resin continuously or discontinuously secured to a surface thereof, or mixtures thereof.

14. The hygroscopic filler for an organic EL getter as claimed in claim 13, wherein the hygroscopic material includes the modified particle, the modified particle including a polymer resin secured to a surface of the hygroscopic material in the form of a coating layer or in the form of projections on the surface of the hygroscopic material.

15. The hygroscopic filler for an organic EL getter as claimed in claim 1, wherein:
the sheet includes a non-woven fabric, and
the hygroscopic material is secured in an amount of about 0.1 wt % to about 99 wt % to the sheet.

16. The hygroscopic filler for an organic EL getter as claimed in claim 1, wherein the hygroscopic filler has an adhesive strength of about 1 gf/cm² to about 100,000 gf/cm², as measured according to a peeling test at a test speed of 50 mm/min.

17. The hygroscopic filler for an organic EL getter as claimed in claim 1, further comprising a coating layer.

18. The hygroscopic filler for an organic EL getter as claimed in claim 17, wherein the coating layer is on a surface of the sheet opposite to a surface of the sheet to which the mixture of the organic binder and the hygroscopic material is secured.

19. The hygroscopic filler for an organic EL getter as claimed in claim 18, wherein the coating layer includes one or more of a polyvinyl acetate resin, a polyvinyl pyrrolidone resin, a polyester resin, a polyolefin resin, a (meth)acrylate resin, a polycarbonate resin, an acrylonitrile resin, a cellulose acetate, an epoxy resin, a phenoxy resin, a siloxane resin, a sulfone resin, a polyamide resin, a polyurethane resin, a polyvinyl resin, a urethane acrylate resin, or a fluorine resin.

20. The hygroscopic filler for an organic EL getter as claimed in claim 1, wherein the hygroscopic filler has a thickness of about 5 μm to about 500 μm.

21. A method of manufacturing a hygroscopic filler for an organic electroluminescent (EL) getter, the method comprising:
preparing a sheet having pores;
impregnating a mixture of a hygroscopic material and a binder into the sheet; and
drying or curing the sheet having the mixture impregnated therein to secure the binder and the hygroscopic material to the sheet.

22. The method of manufacturing a hygroscopic filler for an organic EL getter as claimed in claim 21, wherein:
the mixture of the hygroscopic material and the binder is present in an amount of about 10 parts by weight to about 2,000 parts by weight, based on 100 parts by weight of the sheet, and
a weight ratio of the hygroscopic material to the binder is about 1:9 to about 9:1 in terms of parts by weight.

23. The method of manufacturing a hygroscopic filler for an organic EL getter as claimed in claim 21, wherein the mixture further includes a solvent.

24. The method of manufacturing a hygroscopic filler for an organic EL getter as claimed in claim 21, wherein the method includes the curing, the curing including UV curing or heat curing.

25. A method of manufacturing a hygroscopic filler for an organic electroluminescent (EL) getter, the method comprising:
preparing a sheet having pores;
coating a mixture of a hygroscopic material and a binder on the sheet; and
drying or curing the sheet having the mixture coated thereon to secure the binder and the hygroscopic material to the sheet.

26. An organic electroluminescent device comprising a getter including the hygroscopic filler for an organic EL getter as claimed in claim 1.

27. An organic electroluminescent (EL) device, comprising:
a substrate;
an organic electroluminescent unit on one surface of the substrate, the organic electroluminescent unit including a first electrode, an organic light emitting layer, and a second electrode;
a sealing cap coupled with the substrate to accommodate the organic electroluminescent unit therein; and
a getter within the sealing cap, the getter including the hygroscopic filler for an organic EL getter as claimed in claim 1.
